(19) United States
(12) Patent Application Publication
(10) Pub. No.: US 2017/0245368 A1
(43) Pub. Date: Aug. 24, 2017

(54) ELECTRONIC CIRCUITS COMPRISING ENERGETIC SUBSTRATES AND RELATED METHODS

(71) Applicant: BATTELLE ENERGY ALLIANCE, LLC., Idaho Falls, ID (US)

(72) Inventors: MICHAEL A. DANIELS, IDAHO FALLS, ID (US); RESTON A. CONDIT, IDAHO FALLS, ID (US); JOEL A. JOHNSON, RIGBY, ID (US); RONALD J. HEAPS, IDAHO FALLS, ID (US); RONALD S. WALLACE, UCON, ID (US)

(21) Appl. No.: 15/046,970

(22) Filed: Feb. 18, 2016

(51) Int. Cl. H05K 1/18; H05K 3/30; H05K 3/00

(52) U.S. Cl. CPC H05K 1/181; H05K 3/0011; H05K 3/303

(57) ABSTRACT

A self-protecting electronic circuit may include an energetic substrate comprising an energetic material, a plurality of traces disposed onto the energetic substrate, and at least one surface component couple to the plurality of trace. The self-protecting electronic circuit may optionally include a non-platable insulator disposed on portion of the energetic substrate not having the plurality of traced disposed thereon. The at least one surface component may include an activation mechanism for initiating the energetic substrate. Methods for making a self-protecting electronic circuit include forming an energetic substrate, coating the energetic substrate with an insulator, removing at least a portion of the insulator from the energetic substrate, and disposing at least one trace onto the energetic substrate.

### CROSS-REFERENCE TO RELATED APPLICATION

The present application is related to co-pending U.S. patent application Ser. No. 15/______ (Attorney Docket No. 2939-P13020US), “ENERGETIC POTTING MATERIALS, ELECTRONIC DEVICES POTTED WITH THE ENERGETIC POTTING MATERIALS, AND RELATED METHODS,” filed on even date herewith, the entire disclosure of which is hereby incorporated herein by this reference.

### STATEMENT REGARDING FEDERALLY SPONSORED RESEARCH OR DEVELOPMENT

This invention was made with government support under Contract Number DE-AC07-05-ID14517 awarded by the United States Department of Energy. The government has certain rights in the invention

### TECHNICAL FIELD

This disclosure relates generally to electronic circuits comprising energetic substrates and to methods of making electronic circuits on energetic substrates.

### BACKGROUND

Electronic circuits often contain proprietary, confidential, or otherwise sensitive information. The proprietary information may be in one or more of the structure, circuitry, layout, design, or data stored in memory of the electronic circuit. Some attempts to protect the proprietary information contained in electronic circuits include thin films of explosive or pyrotechnic compositions disposed on a glass substrate, as described in U.S. Pat. No. 3,882,323, to Smolker, issued May 6, 1975. However, the glass substrate is often located between the thin film and the circuitry and provides at least some protection to the circuitry. As a result, the substrate often protects the circuitry from being completely destroyed by the thin film. Furthermore, with the right expertise, the thin film can be removed from the circuit and the proprietary circuitry kept intact.

Other attempts to protect proprietary information in electronic circuits include attaching a centralized explosive compound to the circuit. However, the protection provided by a centralized explosive compound attached to a conventional circuit is limited in that the explosive compound can be removed without destroying the electronic circuit. Furthermore, a centralized explosive may fail to destroy all of the proprietary information contained on a circuit.

### BRIEF SUMMARY

Some embodiments of the present disclosure include a self-protecting electronic circuit. The self-protecting electronic circuit may include an energetic substrate having an energetic material, a plurality of traces disposed onto the energetic substrate, and at least one surface component coupled to the plurality of traces.

Some embodiments of the present disclosure include a self-protecting electronic circuit. The self-protecting electronic circuit may include an energetic substrate including an energetic material and a filler material, a plurality of traces disposed on the energetic substrate, a non-platable insulator disposed on portions of the energetic substrate not having the plurality of traces disposed thereon, and a plurality of surface components coupled to the plurality of traces, the plurality of surface components including an activation mechanism for initiating the energetic substrate.

Yet further embodiments include methods of making a self-protecting electronic circuit. The method may include forming an energetic substrate, coating the energetic substrate with an insulator, removing at least a portion of the insulator from the energetic substrate, disposing at least one trace onto the energetic substrate where the insulator of the energetic substrate has been removed, and coupling at least one surface component to the at least one trace.

### BRIEF DESCRIPTION OF THE DRAWINGS

For a detailed understanding of the present disclosure, reference should be made to the following detailed description, taken in conjunction with the accompanying drawings, in which like elements have generally been designated with like numerals, and wherein:

FIG. 1 is a perspective view of a self-protecting electronic circuit according to an embodiment of the present disclosure;

FIG. 2 is a side cross-sectional view of the self-protecting electronic circuit of FIG. 1;

FIG. 3 is a side cross-sectional view of a self-protecting electronic circuit according to another embodiment of the present disclosure;

FIG. 4 is a side cross-sectional view of a self-protecting electronic circuit according to another embodiment of the present disclosure;

FIG. 5 is a flow chart of acts involved in one embodiment of a process for making a self-protecting electronic circuit according the present disclosure; and

FIG. 6 is a perspective view of an electronic circuit on an energetic substrate according to an embodiment of the present disclosure.

### DETAILED DESCRIPTION

The illustrations presented herein are not actual views of any particular electronic circuit, trace, energetic substrate, or any component, but are merely idealized representations, which are employed to describe the present invention.

As used herein, any relational term, such as “first,” “second,” etc., is used for clarity and convenience in understanding the disclosure and accompanying drawings, and does not connote or depend on any specific preference or order, except where the context clearly indicates otherwise.

Embodiments of the present disclosure may include a self-protecting electronic circuit having a protective mechanism that can be used to protect proprietary circuitry, should the electronic circuit become stolen, lost, misplaced, or moved from a designated area. As used herein, the terms “proprietary circuitry” may refer to aspects of an electronic circuit that are confidential, proprietary, and/or otherwise sensitive. For example, the terms “proprietary circuitry” may refer to a structure, layout, or design of an electronic circuit; structure, layout or design of one or more components of an electronic circuit; data stored in memory of an electronic circuit, and\or so-called “firmware” embedded in a processor of an electronic circuit.

Embodiments of the present disclosure may include a self-protecting electronic circuit having a protective mechanism that can be used to render at least a portion (e.g., a majority) of the electronic circuit inoperable, to deform at least a portion of the electronic circuit beyond repair, to fragment at least a portion of the electronic circuit beyond repair, and/or to burn away at least a portion of the electronic circuit. As used herein, the term “fragment” may refer to bursting and/or shattering at least a portion of the electronic circuit.

Some embodiments of the present disclosure may include a self-protecting electronic circuit that includes an energetic substrate that may be used to destroy at least a portion of the electronic circuit. For example, a portion of the electronic circuit may be destroyed if that portion of the electronic has been at least substantially ruined structurally by, for example, melting and/or burning away that portion of the electronic circuit. In another non-limiting example, a portion of an electronic circuit may be destroyed if that portion of the electronic circuit is shattered or significantly deformed such that an original form of that portion of the electronic circuit cannot be determined from the shattered or deformed portion.

Some embodiments of the present disclosure may include a self-protecting electronic circuit that includes an energetic substrate that can be used to burn away and/or fragment least a portion of the electronic circuit in order to damage or render the electronic circuit at least partially (e.g., substantially) useless or inoperable, for example, such that it cannot reasonably perform its intended function, the circuit cannot be repaired, data cannot be recovered from the circuit, or the circuit cannot be reverse-engineered. In some embodiments, the energetic substrate may melt at least a portion of the electronic circuit to form one or more depressions, openings, or holes in a device by igniting an energetic material within the energetic substrate such as a thermite and contacting components of the electronic circuit (e.g., traces and active and inactive surface components) with molten metal. As used herein the term “melt” may refer to at least partially liquefying a portion of a device through application of heat, which term may also encompass burning away a portion of the electronic circuit through heat. Some embodiments of the present disclosure may include a self-protecting electronic circuit that includes an energetic substrate that can be used to destroy at least a portion of the electronic circuit in order to deform a layout, structure, and/or pattern of the electronic circuit such that a layout, structure, and/or pattern of the electronic circuit cannot be deciphered, repaired or replicated.

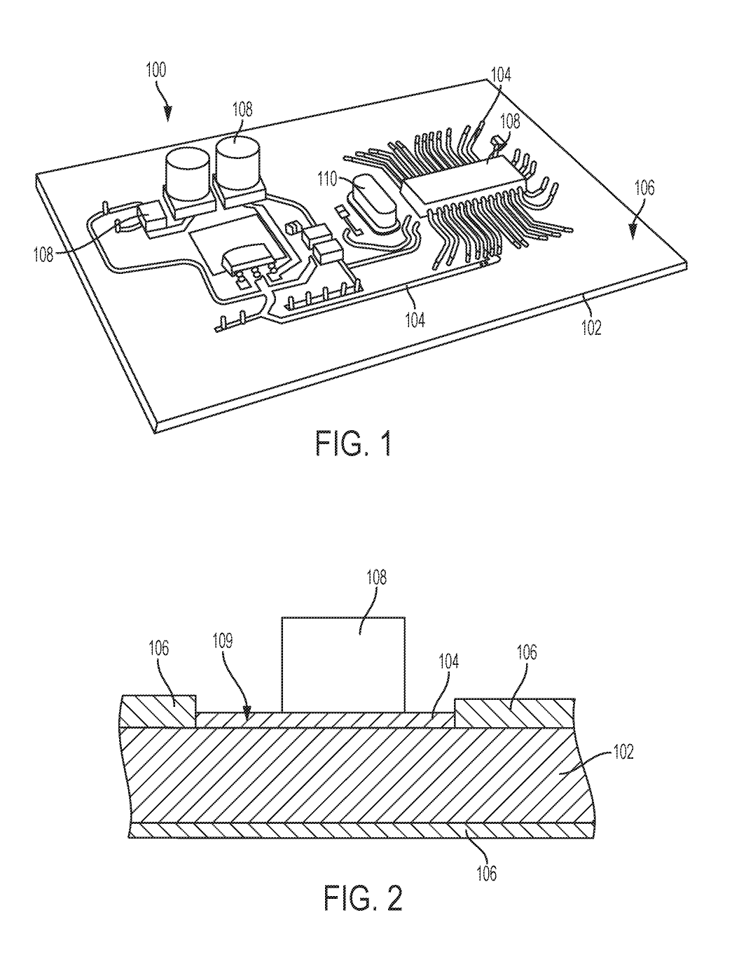

FIG. 1 is perspective view of a self-protecting electronic circuit 100 according to an embodiment of the present disclosure. The electronic circuit 100 may include an energetic substrate 102, a plurality of conductive traces 104, an insulator 106, and at least one active or inactive surface component 108. FIG. 2 is a cross-sectional view of the self-protecting electronic circuit 100 of FIG. 1. Referring to FIGS. 1 and 2 together, in some embodiments, the plurality of traces 104 (e.g., circuity interconnections such as a printed circuit pattern) may be disposed directly on at least one surface 109 of the energetic substrate 102. The insulator 106, which may also be characterized as a passivation material, may be disposed on portions of the energetic substrate 102 not having traces 104 disposed thereon. The surface components 108 may be coupled to the plurality of traces of the electronic circuit 100.

The plurality of traces 104 may be applied directly to the at least one surface 109 of the energetic substrate 102. In other words, as the plurality of traces 104 are applied directly to the energetic substrate 102, there may not be any material (e.g., other layers of material) between the energetic substrate 102 and the plurality of traces 104. In some embodiments, the plurality of traces 104 may be applied through additive or subtractive processes. For example, the plurality of traces 104 may be applied directly to the at least one surface 109 of the energetic substrate 102 through one or more of vapor deposition, lamination, electroplating or electroless plating, printing, coating, masking, patterning, etching, or other processes known in the art. To facilitate description of the electronic circuit 100, applying the plurality of plurality of traces 104 to the energetic substrate 102 will be referred to herein as “plating” the plurality of traces 104 or the plurality of traces 104 being “plated” onto the energetic substrate 102. However, it is understood that, as used herein, the plurality of traces 104 being “plated” onto the energetic substrate 102 may refer any of the above-listed processes for applying the plurality of traces 104 onto the energetic substrate 102. In some embodiments, the plurality of traces 104 may be plated directly onto the at least one surface 109 of the energetic substrate 102 in a desired pattern of the electronic circuit 100. In other embodiments, at least a portion of the at least one surface 109 of the energetic substrate 102 may be entirely plated with a material to be used as traces 104 (e.g., a plate or foil), and portions of the material may be subtracted (e.g., removed) to form the desired pattern of the plurality of traces 104. The material may be subtracted through one or more of laser ablation, chemical etching, milling, etc. In some embodiments, the plurality of traces 104 may be applied to one or more surfaces of the energetic substrate 102. The plurality of traces 104 may comprise copper or any other known conductor used in circuits and suitable for the particular application of the electronic circuit 100 and the environment in which the electronic circuit 100 is to be used.

The energetic substrate 102 may be non-conductive and, in some embodiments, may at least substantially entirely comprise an energetic material. As used herein, the terms “energetic material” may refer to one or more of explosive materials, propellant materials, incendiary compositions, priming compositions, pyrotechnic compositions, or other combustible materials. For example, the terms “energetic material” may refer to one or more of thermite, thermate, Semtex, Torpex, C-4, TNT, or other known explosives or pyrotechnic compositions. As a result, in some embodiments, the energetic substrate 102 may explode, burn (e.g., combust), and/or incinerate in response to an initiation. As used herein, the term “initiation” and any derivative terms may mean that the energetic substrate 102 is subjected to or supplied with energy from an energy source that is greater than or equal to an activation energy of the energetic material of the energetic substrate 102. As used herein, the terms “activation energy” may refer to an amount of energy that is required to cause a given energetic material to react (e.g., explode, incinerate, combust, burn, etc.). In other words, the term “initiation” may refer to igniting the energetic material of the energetic substrate 102. In some embodiments, the energetic substrate 102 may include an energetic material having a high activation energy (e.g., thermite). Stated another way, the energetic substrate 102 may include an energetic material that is less sensitive to (e.g., requires more energy for) initiation. Employing an energetic substrate 102 that includes an energetic material having a high activation energy may help to prevent unintentional initiation of the energetic material from small amounts of energy that may be supplied to the energetic substrate 102 by one or more of the plurality of traces 104, surface components 108, or manufacturing processes for making the electronic circuit 100, as well as unintentional initiation of the energetic material of the energetic substrate 102 during transportation, handling and use of the electronic circuit 100. In other embodiments, the energetic substrate 102 may include an energetic material having a low activation energy. In other words, the energetic substrate 102 may include an energetic material that is more sensitive to (e.g., requires less energy for) initiation. In some embodiments, the energetic substrate may be formed through one or more of cold isostatic pressing, molding, or axial pressing.

In some embodiments, the energetic substrate 102 may include a composite of different materials. For example, the energetic substrate 102 may include an energetic material mixed with a filler material (e.g., binder material). The filler material may include epoxies, plastics, putties, or other known filler materials used in explosives and pyrotechnic composites. When the energetic substrate 102 includes a composite of different materials, the energetic substrate 102 may include an amount (e.g., a sufficient amount) of energetic material to enable the energetic material to at least substantially fully initiate the energetic substrate 102 (e.g., explode, combust, incinerate, etc.) when the energetic substrate 102 is initiated at a single location on the energetic substrate 102 (i.e. there is a sufficient amount of energetic material to allow any reaction to spread at least substantially throughout the entire energetic substrate 102). Moreover, the energetic substrate 102 may include an amount of energetic material sufficient to ensure that, when the energetic substrate 102 is initiated, sufficient heat is generated so that at least a substantial portion of the plurality of traces 104 and surface components 108 of the electronic circuit 100 are at least substantially rendered inoperable and/or burned away. For example, upon initiation, the energetic substrate 102 may at least substantially burn, melt, and/or shatter at least a portion of the plurality of traces 104 and surface components 108 of the electronic circuit 100.

Furthermore, in some embodiments, the energetic substrate 102 may include an amount (e.g., a sufficient amount) of filler material to provide the energetic substrate 102 with structural integrity in order to support the circuitry of the electronic circuit 100. In other words, the energetic substrate 102 may include an amount of filler material sufficient to give the energetic substrate 102 a structural integrity at least substantially similar to conventional materials used in the industry as substrates in electronic circuits (e.g., fiberglass reinforced epoxy resin). As a result, the electronic circuit 100 on the energetic substrate 102 may be used for applications in which conventional electronic circuits are used.

In some embodiments, the composition of the energetic substrate 102 may be tailored so that the energetic substrate 102 is at least substantially platable. In other words, the composition of the energetic substrate 102 may be selected such that the energetic substrate 102 may be plated directly on a surface thereof with the plurality of traces 104 (e.g., such that the plurality of traces 104 will sufficiently adhere to the energetic substrate 102) through conventional processes. In some embodiments, as described in further detail in regard to FIG. 0.4, the electronic circuit 100 may include a bonding layer between the plurality of traces and the energetic substrate 102 to enhance adhesion of the plurality of traces 104 and the energetic substrate 102.

In some embodiments, only a portion of the energetic substrate 102 may include energetic material. For example, the energetic material of the energetic substrate 102 may be sized and shaped in a pattern at least substantially similar to a pattern of some or all of the plurality of traces 104 and some or all of the surface components 108 (i.e. circuitry), and an inert material may be used for portions of the energetic substrate 102 not including the plurality of traces 104 or surface components 108 attached thereto.

Still referring to FIGS. 1 and 2, the insulator 106 of the electronic circuit 100 may be disposed on portions of the energetic substrate 102 that are not covered with the plurality of traces 104 or surface components 108 (i.e., having the plurality of traces 104 disposed thereon). In some embodiments, the insulator 106 may include a conformal coating. In some embodiments, the insulator 106 may cover at least substantially entirely any portions of the energetic substrate 102 not have the plurality of traces 104 disposed thereon. In some embodiments, the insulator 106 may be non-platable. In other words, the insulator 106 may not be susceptible to having the plurality of traces 104 disposed thereon (i.e., traces may not adhere to the insulator 106). Having the insulator 106 be non-platable, may assist in manufacturing processes of making the electronic circuit 100 on the energetic substrate 102. For example, the insulator 106 may be applied to the entire energetic substrate 102 and any portions where the plurality of traces 104 are to be plated may be removed. The insulator 106 may be removed from the energetic substrate 102 through laser ablation, chemical etching, reactive ion etching, thermal etching, thermochemical etching, etc.

The above-methods for removing the insulator 106 from the energetic substrate 102 may have energies that are less than the activation energy of the energetic material of the energetic substrate 102. For example, when the insulator 106 is removed through laser ablation, the laser may have a wavelength that will not initiate the energetic substrate 102. In some embodiments, the insulator 106 may be removed through laser ablation using a laser having a short-wavelength. For example, the laser may have a wavelength within the range of about 125 nm to about 370 nm. In some embodiments, the laser may have a wavelength within the range of about 125 nm to about 285 nm. In some embodiments, the laser may have a wavelength within the range of about 125 nm to about 225 nm. In some embodiments, the insulator 106 may be removed through cold ablation with an ultra violet laser (“UV Laser”). In some embodiments, the UV laser may include an excimer laser (i.e., exciplex laser). In some embodiments, the insulator 106 may be removed through cold ablation using a laser having a wavelength within the range of about 260 nm to about 1550 nm. In such embodiments, the laser may have a pulse energy of less than about 1 mJ and a dwell time within the range of 200 ps to about 600 ps.

The insulator 106 may be removed in a pattern of which the plurality of traces 104 is to be plated onto the energetic substrate 102. Afterward, the plurality of traces 104 may be plated onto the energetic substrate 102 in the areas where the insulator 106 was removed. The insulator 106 may serve to protect the energetic substrate 102 during the plating process and may act as a mask to define trace locations and ensure that plurality of traces 104 are not plated onto areas where the plurality of traces 104 are not intended to be plated. Furthermore, the insulator 106 may protect the energetic substrate 102 after the electronic circuit 100 is completed. For example, the insulator 106 may protect the energetic substrate 102 from coming in contact with energy sources that may cause an unintentional initiation of the energetic substrate 102.

The insulator 106 may be applied to the energetic substrate 102 through one or more of brush coating, spray application coating, dipping, selective coating by machine, or any other known method 500. In some embodiments, the insulator 106 may include a polymeric film. For example, the insulator 106 may include one or more of acrylics, epoxies, polyurethane, silicones, parylene, amorphous fluoropolymers, or any other known materials used in insulators covering circuits. Insulator 106 may also comprise a positive or negative photoresist, as known to those of ordinary skill in the art.

The surface components 108 may be coupled to the plurality of traces 104 of the electronic circuit 100. In other words, the surface components 108 may be attached to and in electrical communication with the plurality of traces 104 of the electronic circuit 100. The surface components 108 may be surface-mounted to the plurality of traces 104 of the electronic circuit 100. In some embodiments, the surface components 108 may be semiconductor dice configured as flip-chips bearing solder bumps on pads operably coupled to internal circuitry of a component and surface-mounted to pads of the conductive traces 104 through reflow soldering. Although specific examples are provided herein, the surface components 108 may couple to the plurality of traces 104 using any method known in the art, such as, for example, vapor phase reflow, hot gas convection reflow, infrared reflow, etc. In some embodiments, the surface components 108 may be surface-mounted through direct soldering. In some embodiments, the surface components 108 may be coupled to the plurality of traces 104 by wire bonding. The methods for coupling the surface components 108 to the plurality of traces 104 of the electronic circuits may exhibit energies (e.g., heat levels) at the surface of the energetic substrate 102 bearing the traces 104 and surface components 108 that are less, including a safety factor, than an activation energy of the energetic material of the energetic substrate 102.

The surface components 108 may include conventional active and passive circuit components such as, for example, resistors, capacitors, inductors, semiconductor dice in the form of processors, logic circuits, volatile and nonvolatile memory, system on a chip, etc. In some embodiments, the surface components 108 of the electronic circuit 100 may include an activation mechanism 110 incorporated into the circuit for initiating the energetic substrate 102. In some embodiments, the activation mechanism 110 may include a small (relative to the energetic substrate 102), relatively more sensitive primary explosive that may be used to detonate (e.g., initiate) a relatively less sensitive secondary explosive (i.e., energetic material in the energetic substrate 102). In other words, the primary explosive may have a low activation energy relative to the energetic material of the energetic substrate 102. Using a sensitive primary explosive to initiate the insensitive energetic substrate 102 may provide a predictable initiation of the energetic substrate 102. In some embodiments, the activation mechanism 110 may include a blasting cap mounted to the plurality of traces 104 of the electronic circuit 100. In other embodiments, the activation mechanism 110 may include a bridge wire igniter (e.g., hot wire igniter). In yet other embodiments, the activation mechanism 110 may include a magnesium ribbon (i.e., fuse). In yet other embodiments, the activation mechanism 110 may include a laser ordnance initiator. In some embodiments, the activation mechanism 110 may be ignited or initiated with an electric voltage or current signal received from the electronic circuit 100.

An initiation of the energetic substrate 102 may be caused by a plurality of events. In other words, the activation mechanism 110 of the electronic circuit 100 may be triggered by different occurrences. In some embodiments, the electronic circuit 100 may be in wireless communication with a trigger. For example, the electronic circuit 100 may be in communication with the trigger through one or more of Wi-Fi signals, radio signals, cellular telephone signals, Bluetooth signals, optical signals, etc. The detonation mechanism 110 may be triggered either locally or remotely. Having the electronic circuit 100 in wireless communication with a remote trigger may provide advantages in protecting proprietary circuitry of the electronic circuit 100. For example, in the event that an electronic circuit 100 having proprietary circuitry is stolen, misplaced, and/or lost, the energetic substrate 102 of the electronic circuit 100 may be initiated (e.g., destroyed) by sending an appropriate trigger signal without knowing the exact location of the electronic circuit 100.

In some embodiments, the electronic circuit 100 may include geo-fencing components and the energetic substrate 102 of the electronic circuit 100 may be initiated (e.g., destroyed) in response to the electronic circuit 100 entering or leaving a designated area. In other words, the energetic substrate 102 may be initiated with the activation mechanism 110 when the electronic circuit 100 crosses a boundary of an area. As a result, the electronic circuit 100 having the proprietary circuitry may be confined to a location (e.g., a building or a secure room within a building) and, should the electronic circuit 100 leave the location, the electronic circuit 100 may be destroyed automatically without direct input from a user.

In some embodiments, the electronic circuit 100 may trigger the activation mechanism 110 in response to the electronic circuit 100 being removed from an electronic device (e.g., a computer). For example, the electronic circuit 100 may include surface components 108 that determine when an electrical connection between the electronic circuit 100 and the electronic device is broken, and when the electrical connection is broken, the activation mechanism 110 may be triggered, the energetic substrate 102 may be initiated, and the electronic circuit 100 may be destroyed. In some embodiments, the activation mechanism 110 of the electronic circuit 100 may be physically wired to a trigger and may be triggered intentionally by a user.

Having the plurality of traces 104 and surface components 108 of the electronic circuit 100 applied and mounted directly to onto an energetic substrate 102 may provide advantages in applications where a structure, layout, design of the plurality of traces 104 as well as of components, and/or data stored in memory of the electronic circuit 100 or embedded as firmware is proprietary, confidential, or otherwise sensitive. For example, having the plurality of traces 104 and surface components 108 of the electronic circuit 100 applied and mounted directly to onto an energetic substrate 102 may help to ensure that, should the electronic circuit 100 become misplaced or stolen, the electronic circuit 100 may be destroyed and the proprietary circuitry may be secured. Furthermore, unlike known methods where explosive devices are merely attached to the electronic circuit 100 to provide protection and can be removed, having the plurality of traces 104 and surface components 108 of the electronic circuit 100 applied and mounted directly to onto an energetic substrate 102 ensures that the electronic circuit 100 cannot be removed from the energetic substrate 102 without destroying the electronic circuit 100. As a result, having the plurality of traces 104 and surface components 108 of the electronic circuit 100 applied and mounted directly to onto an energetic substrate 102 provides additional protection in comparison to known methods of protecting proprietary circuitry with explosives. Moreover, the electronic circuit 100 of the present disclosure provides advantages over other known methods by requiring fewer components to protect the electronic circuit 100. Additionally, the electronic circuit 100 of the present disclosure may enable easier packaging and add less parasitic mass than other known methods.

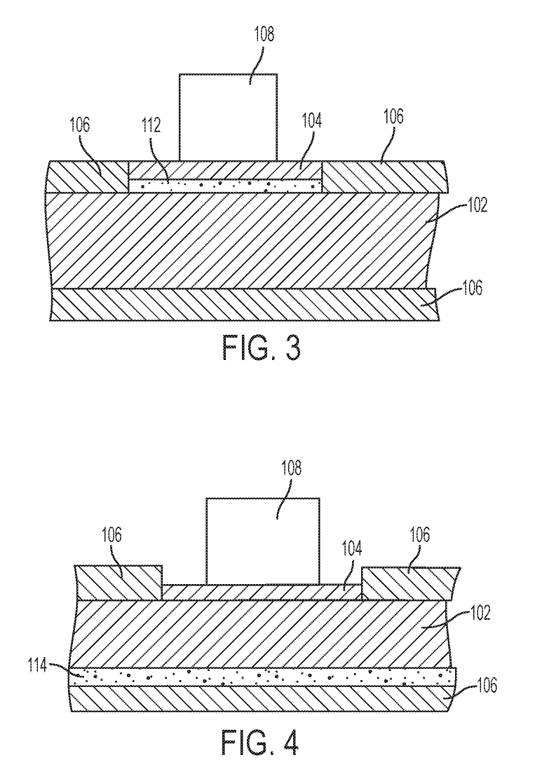

FIG. 3 shows a cross-sectional side view of a self-protecting electronic circuit 100 according to another embodiment of the present disclosure. In some embodiments, the electronic circuit 100 may include a bonding layer 112 between the plurality of traces 104 and the energetic substrate 102. In some embodiments, the bonding layer 112 may include an adhesive layer. The adhesive layer may include one or more of polyimide, polyester, acrylic, epoxy, fluoropolymer, or phenolic adhesives. In some embodiments, the bonding layer 112 may include a layer of a metal material (e.g., a catalyst layer) that may bond to the energetic substrate 102 and the material of the plurality of traces 104. In some embodiments, the bonding layer 112 may include ultra-violet curable adhesives. In some embodiments, the bonding layer 112 may include a priming layer of a ultra-violet curable adhesive disposed directly on the energetic substrate 102 and a phenolic adhesive disposed on the priming layer of a ultra-violet curable adhesive. The priming layer of a ultra-violet curable adhesive may help to prevent other adhesives from seeping into (e.g., infiltrating) the energetic substrate 112 and interfering with the energetic substrate at least substantially fully initiating (e.g., “dudding” the energetic substrate 112).

FIG. 4 shows a cross-sectional side view of a self-protecting electronic circuit 100 according to another embodiment of the present disclosure. In some embodiments, the electronic circuit 100 may include a backing layer 114 attached to the energetic substrate 102. The backing layer 114 may be attached to a side of the energetic substrate 102 opposite the plurality of traces 104. The backing layer 114 may provide additional structural integrity to the energetic substrate 102 when the energetic material and binder of the energetic substrate 102 do not provide sufficient structural integrity for an application (e.g., use) of the electronic circuit 100. In some embodiments, the backing layer 114 may be made of conventional materials used to make substrates for electronic circuits. For example, the backing layer 114 may be made of fiberglass reinforced epoxy resin. In other embodiments, the backing layer 114 may be made of one or more of a metallic, ceramic, or polymeric material. In some embodiments, the backing layer 114 may help direct the energy of the energetic material of the energetic substrate when initiated toward the traces 104 and surface components 108, enabling a smaller volume of energetic material to be employed, in the form of a thinner or smaller energetic substrate 102.

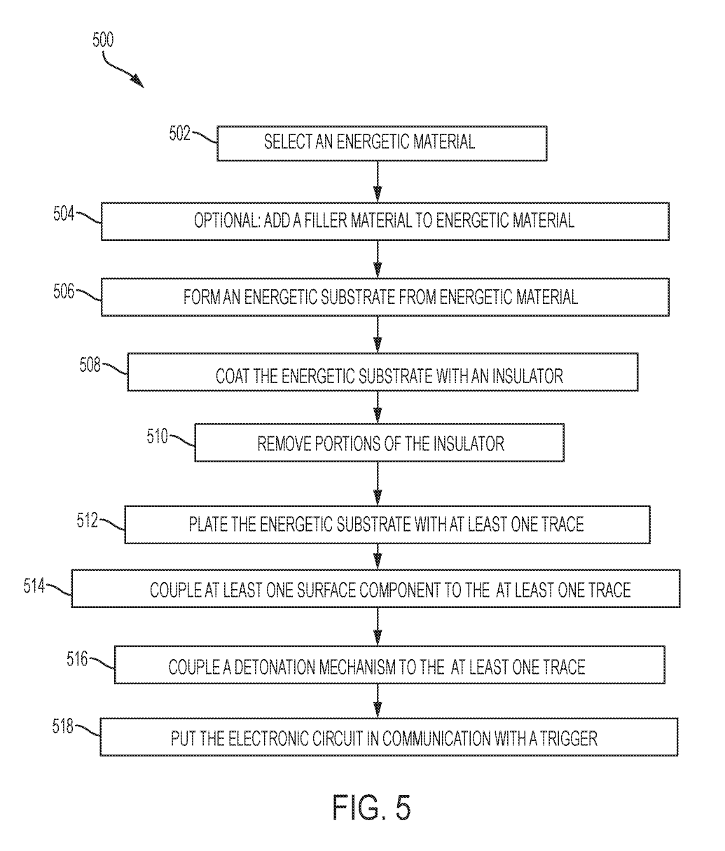

FIG. 5 shows acts involved in one embodiment of a process 500 of making a self-protecting electronic circuit 100 according to an embodiment of the present disclosure. Referring to FIGS. 1, 2, and 5 together, the process 500 may include selecting an energetic material with a capability to destroy an electronic circuit 100, as represented in act 502. In some embodiments, selecting an energetic material may include selecting one or more of thermite, thermate, Semtex, Torpex, C-4, TNT, or other known explosive, propellant or pyrotechnic compositions. Optionally, a filler material may be added to the energetic material, as represented in action 504. The filler material may be added to the energetic material to give a resulting composition sufficient structural integrity to act as a substrate for the electronic circuit 100. An energetic substrate 102 may be formed from the energetic material, as represented in act 506.

The energetic substrate 102 may be coated with an insulator 106, as represented in act 508. In some embodiments, coating the energetic substrate 102 with the insulator 106 may include coating the energetic substrate 102 with a non-platable insulator 106. The insulator 106 may be applied to the energetic substrate 102 through one or more of brush coating, spray application coating, dipping, selective coating by machine, or any other known technique. After the energetic substrate 102 has been coated with the insulator 106, at least a portion of the insulator 106 may be removed from the energetic substrate 102, as represented in act 510. Removing at least a portion of the insulator 106 from the energetic substrate 102 may include removing at least a portion of the insulator 106 through laser ablation, chemical etching, thermal etching, etc. In some embodiments, removing at least a portion of the insulator 106 through laser ablation may include removing at least a portion of the insulator 106 with a laser having a short wavelength. For example, the laser may have wavelength that will not initiate the energetic material of the energetic substrate 102. In some embodiments, the laser may be a UV laser. In some embodiments, the UV laser may be an excimer laser. The insulator 106 may be removed in a pattern in which the at least one trace is to be plated onto the energetic substrate 102.

Where the insulator 106 has been removed from the energetic substrate 102, the energetic substrate 102 may be plated with at least one trace 104, as represented in act 512. In some embodiments, the at least one trace 104 may be plated directly onto at least one surface 109 of the energetic substrate 102. In other embodiments, a bonding layer 112 (FIG. 4) may be applied to the at least one surface 109 of the energetic substrate 102, and the at least one trace 104 may be applied to the bonding layer 112. The at least one trace 104 may be applied through one or more of vapor deposition, lamination, plating, coating, or other processes known in the art.

Surface components 108 may be coupled to the at least one trace 104, as represented in act 514. The surface components 108 may be coupled to the at least one trace 104 through one or more of reflow or direct soldering.

An activation mechanism 110 for initiating the energetic substrate 102 may be coupled to the at least one trace 104, as represented in act 516. Coupling an activation mechanism 110 to the at least one trace 104 may include coupling one or more of a blasting cap, bridge wire igniter, fuse, or laser ordnance initiator to the at least one trace 104.

The electronic circuit 100 may be put in communication with a trigger, as represented in act 518. Putting the electronic circuit 100 in communication with the trigger may include putting a surface component of the electronic circuit 100 in wireless communication with the trigger. In some embodiments, putting the electronic circuit 100 in communication with the trigger may include including geo-fencing components in the electronic circuit 100. In some embodiments, putting the electronic circuit 100 in communication with the trigger may include configuring the electronic circuit 100 to determine when an electrical connection between the electronic circuit 100 and an electronic device is broken.

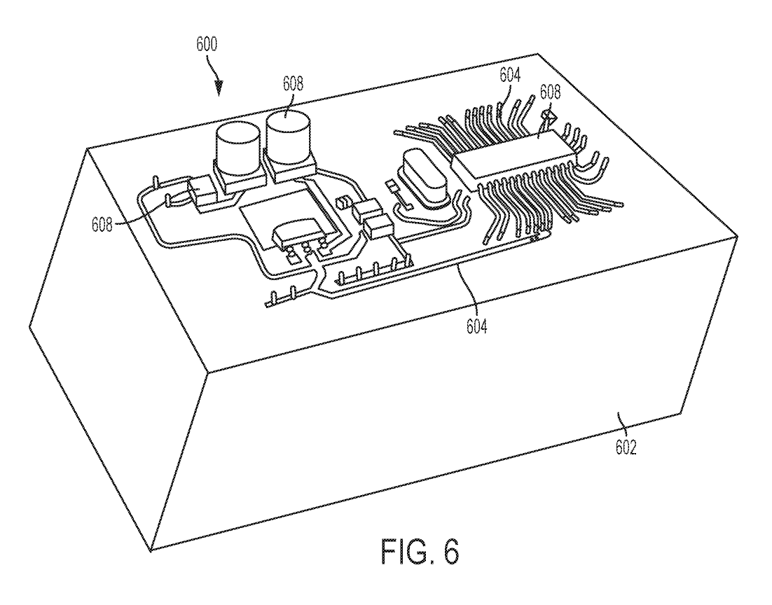

FIG. 6 shows a perspective view of an explosive device comprising an electronic circuit 600 having an energetic substrate 602 according to an embodiment of the present disclosure. In some embodiments, the plurality of traces 604 and surface components 608 of the electronic circuit 600 may be disposed on an energetic substrate 602 to form an explosive device that may be used for destroying structures in addition to the electronic circuit 600 an in some proximity thereto. For example, the explosive device may be used in demolition. Of course, in such an embodiment, an explosive energetic material is employed, the selection and mass of which may be determined by one of ordinary skill in the art based at least in part on a desired blast radius. One application of such a device is for military and law enforcement applications, wherein the electronic circuit 600 as fabricated on the energetic substrate 602 is for the sole purpose of receiving a trigger signal to trigger an activation mechanism 110 (not shown) and initiate the energetic material of energetic substrate 602. In such instances, the mass and shape of the energetic substrate may be tailored to provide a directed explosive energy. Applying the plurality of traces 604 and surface components 608 directly onto energetic substrate 602 may reduce cost in demolition procedures or other procedures where explosives are used. For example, applying the plurality of traces 604 and surface components 608 directly onto the energetic substrate 602 may reduce a need for parasitic circuitry in the explosive device, a size of the explosive device, and a complexity of the explosive device. Furthermore, applying the plurality of traces 604 and surface components 608 directly onto the energetic substrate 602 may increase a reliability of the explosive device (e.g., reliability that the explosive device will explode upon command) by reducing a number of potential failure points of the explosive device by reducing circuitry. Moreover, applying the plurality of traces 604 and surface components 608 directly onto the energetic substrate 602 may decrease an ability of an adverse party to disarm the explosive device.

The embodiments of the disclosure described above and illustrated in the accompanying drawings do not limit the scope of the disclosure, which is encompassed by the scope of the appended claims and their legal equivalents. Any equivalent embodiments are within the scope of this disclosure. Indeed, various modifications of the disclosure, in addition to those shown and described herein, such as alternate useful combinations of the elements described, will become apparent to those skilled in the art from the description. Such modifications and embodiments also fall within the scope of the appended claims and equivalents.

What is claimed is:

1. A self-protecting electronic circuit, comprising:
an energetic substrate comprising an energetic material;
a plurality of traces disposed onto the energetic substrate; and
at least one surface component coupled to the plurality of traces.

2. The self-protecting electronic circuit of claim 1, the energetic substrate further comprising a filler material.

3. The self-protecting electronic circuit of claim 2, wherein the energetic material comprises thermite.

4. The self-protecting electronic circuit of claim 1, wherein the at least one surface component include an activation mechanism.

5. The self-protecting electronic circuit of claim 4, wherein the activation mechanism comprises a bridgewire igniter.

6. The self-protecting electronic circuit of claim 1, further comprising an insulator covering portions of the energetic substrate not having the plurality of traces disposed thereon.

7. The self-protecting electronic circuit of claim 6, wherein the insulator comprises a conformal coating.

8. The self-protecting electronic circuit of claim 6, wherein the insulator is at least substantially non-platable with traces.

9. The self-protecting electronic circuit of claim 1, wherein the at least one surface component includes at least one trigger component responsive to geo-fencing.

10. A self-protecting electronic circuit, comprising:
an energetic substrate including an energetic material and a filler material;
a plurality of traces disposed on the energetic substrate;
a non-platable insulator disposed on portions of the energetic substrate not having the plurality of traces disposed thereon; and
a plurality of surface components coupled to the plurality of traces, the plurality of surface components including an activation mechanism for initiating the energetic substrate.

11. The self-protecting electronic circuit of claim 10, wherein the activation mechanism is configured for wireless communication responsive to a trigger signal.

12. The self-protecting electronic circuit of claim 10, wherein the plurality of surface components include at least one component responsive to a geo-fencing signal and wherein the activation mechanism is operably coupled to the at least one component and configured to initiate the energetic material responsive to receipt of a geo-fencing signal by the at least one component.

13. The self-protecting electronic circuit of claim 10, further comprising a bonding layer between the plurality of traces and the energetic substrate.

14. The self-protecting electronic circuit of claim 13, wherein the bonding layer comprises an adhesive layer.

15. The self-protecting electronic circuit of claim 13, wherein the bonding layer comprises a layer of metallic material.

16. A method for making a self-protecting electronic circuit, the method comprising:
forming an energetic substrate;
coating the energetic substrate with an insulator;
removing at least a portion of the insulator from the energetic substrate;
disposing at least one trace onto the energetic substrate where the insulator of the energetic substrate has been removed; and
coupling at least one surface component to the at least one trace.

17. The method for making a self-protecting electronic circuit of claim 16, wherein removing at least a portion of the insulator from the energetic substrate comprises removing the insulator through ablation with a laser.

18. The method for making a self-protecting electronic circuit of claim 16, wherein removing at least a portion of the insulator from the energetic substrate comprises removing the insulator through ablation with an ultra-violet laser.

19. The method for making a self-protecting electronic circuit of claim 16, wherein coupling at least one surface component to the at least one trace comprises coupling an activation mechanism to the at least one trace.

20. The method for making a self-protecting electronic circuit of claim 16, wherein forming an energetic substrate comprises forming the energetic substrate from an energetic material and a filler material.
